(19) United States
(12) Patent Application Publication
(10) Pub. No.: US 2026/0244823 A1
(43) Pub. Date: Aug. 20, 2026

(54) SYSTEMS AND METHODS OF VALIDATING SIMULATED DATA FOR DEVELOPING AUTONOMOUS VEHICLES USING CLASSIFICATION

(71) Applicant: Torc Robotics, Inc., Blacksburg, VA (US)

(72) Inventors: Maximilian Koeper, Ostfildern (DE); Marius Bause, Stuttgart (DE); Johannes Plaum, Boeblingen (DE); Andre Scholich, Leipzig (DE)

(21) Appl. No.: 19/053,880

(22) Filed: Feb. 14, 2025

(51) Int. Cl. G06F 30/27

(52) U.S. Cl. CPC G06F 30/27

(57) ABSTRACT

A simulation validation computing device including at least one processor in communication with at least one memory device. The at least one processor programmed to receive a real-world dataset of environments in which an autonomous vehicle could operate. The real-world dataset includes data generated based on sensor data of the environments. The at least one processor is also programmed to receive a simulated dataset of the environments. The simulated data generated by a data generator. Further, the at least one processor is programmed to classify, via a classification machine learning model, the real-world dataset, and the simulated dataset, by inputting the datasets into the classification machine learning model. The classification machine learning model is configured to classify input data into two classes. Additionally, the at least one processor programmed to validate the simulated dataset as being realistic based on classification and output a validation result of the simulated dataset.

### TECHNICAL FIELD

The field of the disclosure relates generally to autonomous vehicles and, more specifically, systems and methods of validating simulated data for use in developing autonomous vehicles.

### BACKGROUND OF THE INVENTION

Autonomous vehicle developers rely heavily on simulated data to develop an autonomous computing system of an autonomous vehicle and evaluate the performance and safety of the systems, often citing billions of simulated miles driven under various conditions. Simulated data should realistically resemble the real-world to provide meaningful measurements of the performance of the autonomous vehicle in the real-world. Accordingly, it is desirable to improve the way in which simulations used to develop the autonomous vehicle are validated.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY OF THE INVENTION

In one aspect, the disclosed simulation validation computing device for validating simulated data for use in developing an autonomy computing system of an autonomous vehicle, includes at least one processor in communication with at least one memory device. The at least one processor programmed to receive a real-world dataset of environments in which an autonomous vehicle could operate. The real-world dataset includes data generated based on sensor data of the environments. The at least one processor is also programmed to receive a simulated dataset of the environments. The simulated data generated by a data generator. Further, the at least one processor is programmed to classify, via a classification machine learning model, the real-world dataset, and the simulated dataset, by inputting the datasets into the classification machine learning model. The classification machine learning model is configured to classify input data into two classes. Additionally, the at least one processor programmed to validate the simulated dataset as being realistic based on classification and output a validation result of the simulated dataset.

In another aspect, the disclosed simulation validation method for validating simulated data for use in developing an autonomy computing system of an autonomous vehicle, includes receiving a real-world dataset of environments in which an autonomous vehicle could operate. The real-world dataset includes data generated based on sensor data of the environments. The method also includes receiving a simulated dataset of the environments. The simulated data generated by a data generator. Additionally, the method includes classifying, via a classification machine learning model, the real-world dataset and the simulated dataset, by inputting the datasets into the classification machine learning model. The classification machine learning model is configured to classify input data into two classes. Further, the method includes validating the simulated dataset as being realistic based on classification and outputting a validation result of the simulated dataset.

In yet another aspect, the disclosed non-transitory computer-readable medium stores instructions executable by a processor. The instructions causing the processor to perform a method for validating simulated data for use in developing an autonomy computing system of an autonomous vehicle. The method includes receiving a real-world dataset of environments in which an autonomous vehicle could operate. The real-world dataset includes data generated based on sensor data of the environments. The method also includes receiving a simulated dataset of the environments. The simulated data generated by a data generator. Additionally, the method includes classifying, via a classification machine learning model, the real-world dataset, and the simulated dataset, by inputting the datasets into the classification machine learning model. The classification machine learning model is configured to classify input data into two classes. Further, the method includes validating the simulated dataset as being realistic based on classification and outputting a validation result of the simulated dataset.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic diagram of an autonomous vehicle;

FIG. 2 is a block diagram of an autonomous vehicle;

FIG. 3A is a block diagram of an example simulation validation computing device;

FIG. 3B is a schematic diagram of an example environment in which an autonomous vehicle could operate;

FIG. 3C is a schematic diagram an example instance of a behavior;

FIG. 3D is a schematic diagram of an example binary classification plot;

FIG. 3E is a schematic diagram of an example dataset feature plot;

FIG. 4 is a block diagram of an example simulation validation flow chart;

FIG. 5A is a schematic diagram of an example method for training a classification machine learning model;

FIG. 5B is another schematic diagram of the method for training the classification machine learning model as shown in FIG. 5A;

FIG. 6 is a flow chart of an example simulation validation method;

FIG. 7A is a is a block diagram of an example neural network model;

FIG. 7B is a is a block diagram of a neuron in the neural network model shown in FIG. 5A;

FIG. 8 is a block diagram of an example computing device;

FIG. 9 is a block diagram of an example server computing device; and

FIG. 10 is a block diagram of an example user computing device.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing. The drawings are not to scale unless otherwise noted.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure.

The disclosed systems and methods are described, for clarity, using certain terminology when referring to and describing relevant components within the disclosure. Where possible, common industry terminology is employed in a manner consistent with its accepted meaning. Unless otherwise stated, such terminology should be given a broad interpretation consistent with the context of the present application and the scope of the appended claims.

Autonomous vehicles developers rely on a combination of simulated and real-world data to train the various machine learning models that are included in an autonomous vehicle. Generally, simulated data is more cost effective and easier to obtain than real-world data. Therefore, it is advantageous for developers to utilize simulated data to the greatest extent possible when developing autonomous vehicles. A metric often used to describe how safe an autonomous vehicle or system thereof, is how many miles, simulated or otherwise, has the autonomous vehicle or system thereof been driven. However, validating the realism of these simulations, where a high-level scene description drives synthetic outputs for the perception system, is a significant challenge. These simulations require validation to ensure that the scene descriptions accurately represent real-world conditions, which is typically a complex and subjective task. If the simulated data is not representative of the real-world data, the benefits of using simulated data to train autonomous vehicles are lost and may even reduce the level of safe an autonomous vehicle or system thereof is. Accordingly, it is desirable to validate the level of which the simulated data used to train autonomous vehicles represents the real-world.

The present application is directed to systems and methods for simulation validation using a classification machine learning model to address the above-described problems in using simulated data to train autonomous vehicles and systems thereof. This is accomplished by using a classification machine learning model to classify sets of simulated and real-world data to determine if quantifiable differences exist between the datasets. Based on the output of the classification machine learning model, simulated data can be verified and used to develop autonomous vehicle or system thereof. Additionally, improved simulated data can be generated to better resemble real-world data based on the output of the classification machine learning model. Systems and methods described are also advantageous in accounting for critical areas in developing an autonomous vehicle or system thereof. Critical areas are behaviors or situations that pose significant risks to people, the autonomous vehicle, and/or the surroundings. Example critical areas include scenarios that have parameters at the extreme ends of the spectra, such as extreme weather conditions, unexpected objects on the road, and/or unexpected behavior of actors on the road. Real-world data associated with critical areas may be unavailable and is generally challenging and/or expensive to obtain. Accordingly, it is especially desirable to validate the simulated data of critical areas for use to train autonomous vehicles.

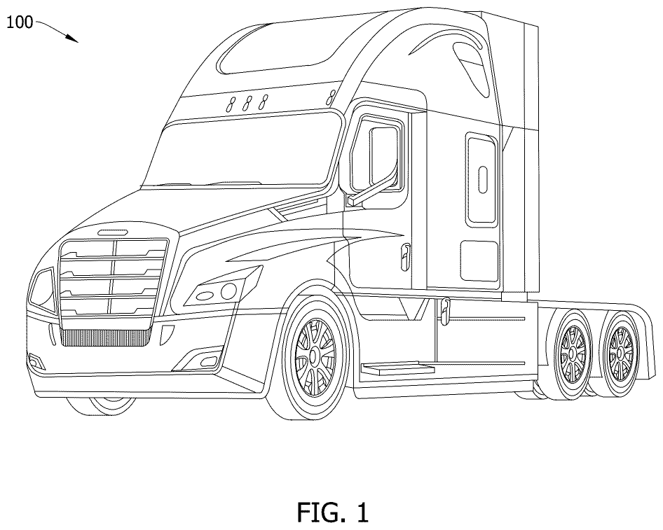

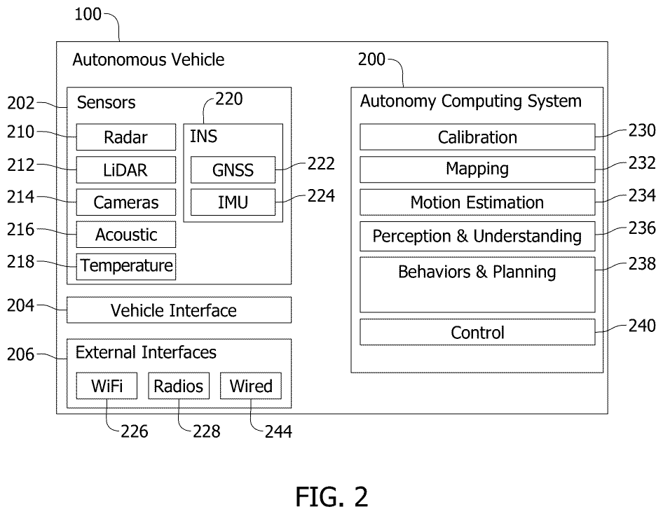

FIG. 1 is a schematic diagram of an autonomous vehicle 100. FIG. 2 is a block diagram of autonomous vehicle 100 shown in FIG. 1. In the example embodiment, autonomous vehicle 100 includes autonomy computing system 200, sensors 202, a vehicle interface 204, and external interfaces 206.

In the example embodiment, sensors 202 may include various sensors such as, for example, radio detection and ranging (radar) sensors 210, light detection and ranging (LiDAR) sensors 212, cameras 214, acoustic sensors 216, temperature sensors 218, or inertial navigation system (INS) 220, which may include one or more global navigation satellite system (GNSS) receivers 222 and one or more inertial measurement units (IMU) 224. Other sensors 202 not shown in FIG. 2 may include, for example, acoustic (e.g., ultrasound), internal vehicle sensors, meteorological sensors, or other types of sensors. Sensors 202 generate respective output signals based on detected physical conditions of autonomous vehicle 100 and its proximity. As described in further detail below, these signals may be used by autonomy computing system 120 to determine how to control operation of autonomous vehicle 100.

Cameras 214 are configured to capture images of the environment surrounding autonomous vehicle 100 in any aspect or field of view (FOV). The FOV can have any angle or aspect such that images of the areas in front of, to the side of, behind, above, or below autonomous vehicle 100 may be captured. In some embodiments, the FOV may be limited to particular areas around autonomous vehicle 100 (e.g., forward of autonomous vehicle 100, to the sides of autonomous vehicle 100, etc.) or may surround 360 degrees of autonomous vehicle 100. In some embodiments, autonomous vehicle 100 includes multiple cameras 214, and the images from each of the multiple cameras 214 may be stitched or combined to generate a visual representation of the multiple cameras'FOVs, which may be used to, for example, generate a bird's eye view of the environment surrounding autonomous vehicle 100. In some embodiments, the image data generated by cameras 214 may be sent to autonomy computing system 200 or other aspects of autonomous vehicle 100, and this image data may include autonomous vehicle 100 or a generated representation of autonomous vehicle 100. In some embodiments, one or more systems or components of autonomy computing system 200 may overlay labels to the features depicted in the image data, such as on a raster layer or other semantic layer of a high-definition (HD) map.

LiDAR sensors 212 generally include a laser generator and a detector that send and receive a LiDAR signal such that LiDAR point clouds (or “LiDAR images”) of the areas in front of, to the side of, behind, above, or below autonomous vehicle 100 can be captured and represented in the LiDAR point clouds. Radar sensors 210 may include short-range radar (SRR), mid-range radar (MRR), long-range radar (LRR), or ground-penetrating radar (GPR). One or more sensors may emit radio waves, and a processor may process received reflected data (e.g., raw radar sensor data) from the emitted radio waves. In some embodiments, the system inputs from cameras 214, radar sensors 210, or LiDAR sensors 212 may be fused or used in combination to determine conditions (e.g., locations of other objects) around autonomous vehicle 100.

GNSS receiver 222 is positioned on autonomous vehicle 100 and may be configured to determine a location of autonomous vehicle 100, which it may embody as GNSS data, as described herein. GNSS receiver 222 may be configured to receive one or more signals from a global navigation satellite system (e.g., Global Positioning System (GPS) constellation) to localize autonomous vehicle 100 via geolocation. In some embodiments, GNSS receiver 222 may provide an input to or be configured to interact with, update, or otherwise utilize one or more digital maps, such as an HD map (e.g., in a raster layer or other semantic map). In some embodiments, GNSS receiver 222 may provide direct velocity measurement via inspection of the Doppler effect on the signal carrier wave. Multiple GNSS receivers 222 may also provide direct measurements of the orientation of autonomous vehicle 100. For example, with two GNSS receivers 222, two attitude angles (e.g., roll and yaw) may be measured or determined. In some embodiments, autonomous vehicle 100 is configured to receive updates from an external network (e.g., a cellular network). The updates may include one or more of position data (e.g., serving as an alternative or supplement to GNSS data), speed/direction data, orientation or attitude data, traffic data, weather data, or other types of data about autonomous vehicle 100 and its environment.

IMU 224 is a micro-electrical-mechanical (MEMS) device that measures and reports one or more features regarding the motion of autonomous vehicle 100, although other implementations are contemplated, such as mechanical, fiber-optic gyro (FOG), or FOG-on-chip (SiFOG) devices. IMU 224 may measure an acceleration, angular rate, and or an orientation of autonomous vehicle 100 or one or more of its individual components using a combination of accelerometers, gyroscopes, or magnetometers. IMU 224 may detect linear acceleration using one or more accelerometers and rotational rate using one or more gyroscopes and attitude information from one or more magnetometers. In some embodiments, IMU 224 may be communicatively coupled to one or more other systems, for example, GNSS receiver 222 and may provide input to and receive output from GNSS receiver 222 such that autonomy computing system 200 is able to determine the motive characteristics (acceleration, speed/direction, orientation/attitude, etc.) of autonomous vehicle 100.

In the example embodiment, autonomy computing system 200 employs vehicle interface 204 to send commands to the various aspects of autonomous vehicle 100 that control the motion of autonomous vehicle 100 (e.g., engine, throttle, steering wheel, brakes, etc.) and to receive input data from one or more sensors 202 (e.g., internal sensors). External interfaces 206 are configured to enable autonomous vehicle 100 to communicate with an external network via, for example, a wired or wireless connection, such as Wi-Fi 226 or other radios 228. In embodiments including a wireless connection, the connection may be a wireless communication signal (e.g., Wi-Fi, cellular, LTE, 5g, Bluetooth, etc.).

In some embodiments, external interfaces 206 may be configured to communicate with an external network via a wired connection 244, such as, for example, during testing of autonomous vehicle 100 or when downloading mission data after completion of a trip. The connection(s) may be used to download and install various lines of code in the form of digital files (e.g., HD maps), executable programs (e.g., navigation programs), and other computer-readable code that may be used by autonomous vehicle 100 to navigate or otherwise operate, either autonomously or semi-autonomously. The digital files, executable programs, and other computer readable code may be stored locally or remotely and may be routinely updated (e.g., automatically or manually) via external interfaces 206 or updated on demand. In some embodiments, autonomous vehicle 100 may deploy with all of the data it needs to complete a mission (e.g., perception, localization, and mission planning) and may not utilize a wireless connection or other connection while underway.

In the example embodiment, autonomy computing system 200 is implemented by one or more processors and memory devices of autonomous vehicle 100. Autonomy computing system 200 includes modules, which may be hardware components (e.g., processors or other circuits) or software components (e.g., computer applications or processes executable by autonomy computing system 200), configured to generate outputs, such as control signals, based on inputs received from, for example, sensors 202. These modules may include, for example, a calibration module 230, a mapping module 232, a motion estimation module 234, a perception and understanding module 236, a behaviors and planning module 238, and a control module or controller 240. These modules may be implemented in dedicated hardware such as, for example, an application specific integrated circuit (ASIC), field programmable gate array (FPGA), or microprocessor, or implemented as executable software modules, or firmware, written to memory and executed on one or more processors onboard autonomous vehicle 100.

Autonomy computing system 200 of autonomous vehicle 100 may be completely autonomous (fully autonomous), semi-autonomous, or with any level of autonomy. In one example, autonomy computing system 200 can operate under Level 5 autonomy (e.g., full driving automation), Level 4 autonomy (e.g., high driving automation), Level 3 autonomy (e.g., conditional driving automation), Level 2 autonomy (e.g., partial driving automation), or Level 1 autonomy (e.g., driver assistance). As used herein the term “autonomous” includes fully autonomous, semi-autonomous, or having any level of autonomy.

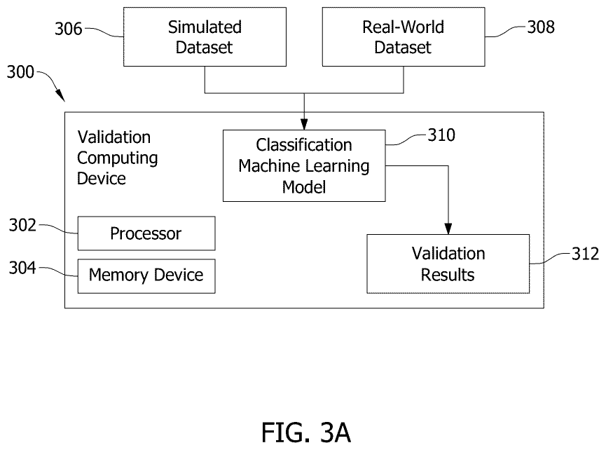

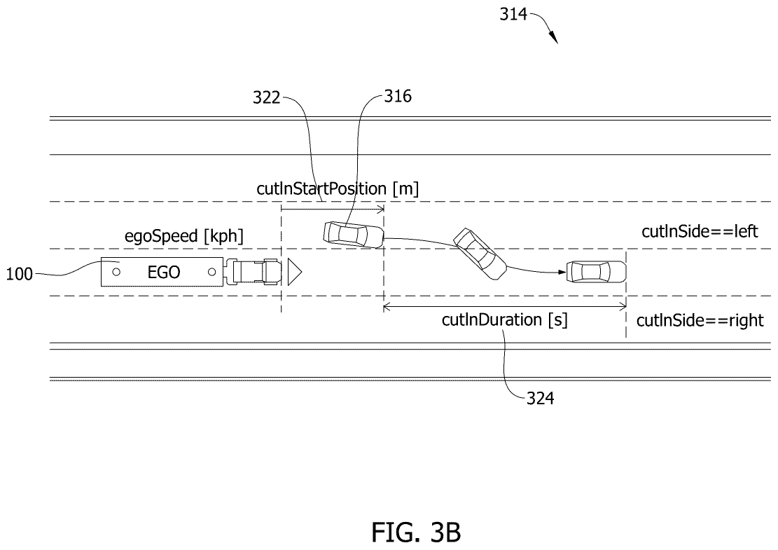

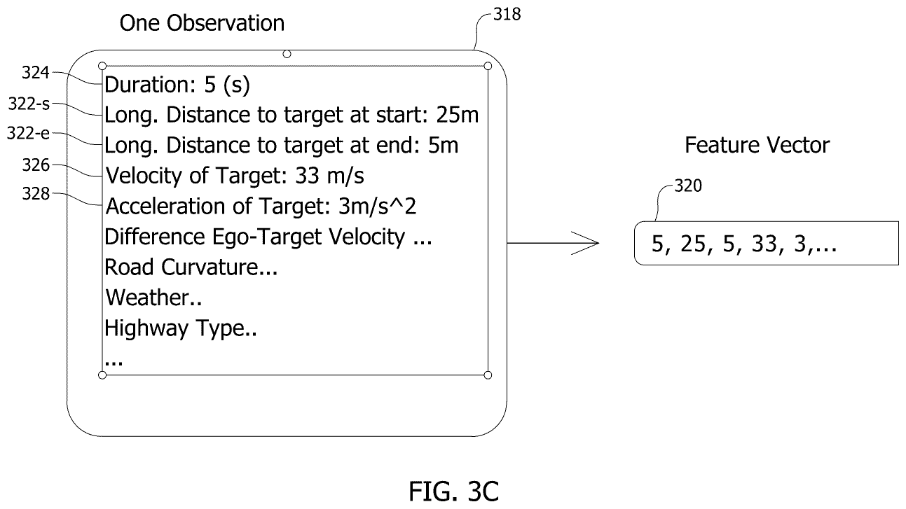

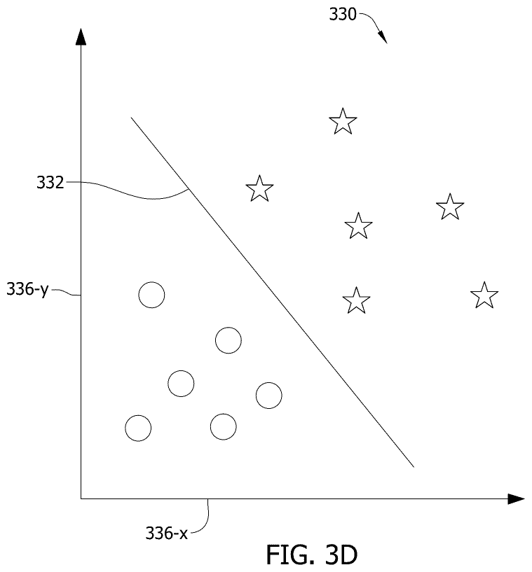

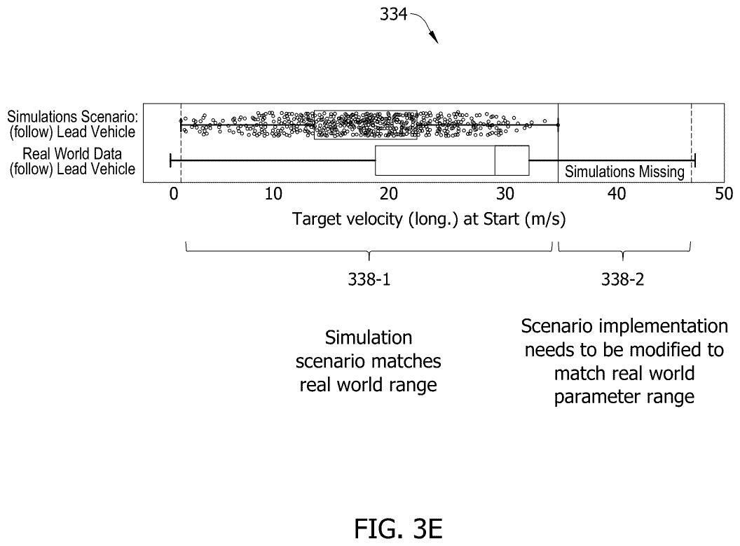

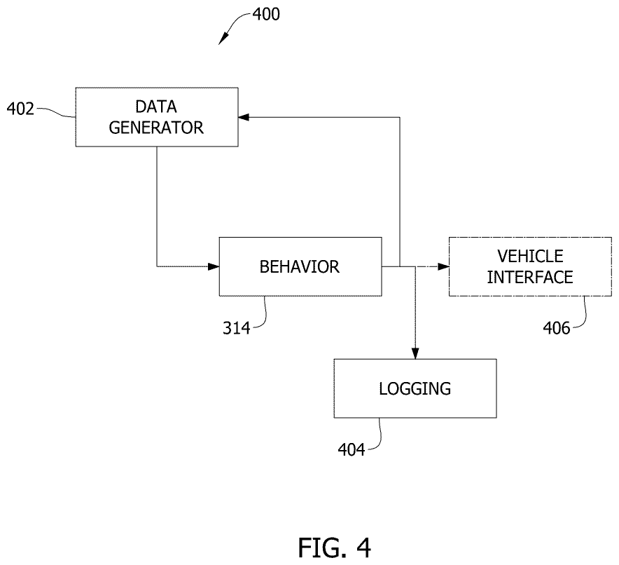

FIG. 3A is a block diagram of an example simulation validation computing device 300. In the example embodiment, simulation validation computing device 300 includes at least one processor 302 in communication with at least one memory device 304. Processor 302 is programmed to receive a real-world dataset 308 representative of environments in which an autonomous vehicle 100 could operate. Real-world dataset 308 is generated based on sensor data 202 from the environments. Processor 302 is also programmed to receive a simulated dataset 306, which includes a plurality of simulated instances 318 (shown in FIG. 3C, described later) representative of environments in which an autonomous vehicle 100 could operate. The simulated data is generated by a data generator 402 (shown in FIG. 4, described later). Processor 302 is further programmed to classify, via a classification machine learning model 310, classes, for example, two classes of a real-world dataset and a simulated dataset. The datasets are input into the classification machine learning model 310. Classification machine learning model 310 is configured to classify input data into two classifications and output a confidence level for classifying real-world dataset 308 and simulated dataset 306 into the two classifications. Processor 302 is programmed to validate simulated dataset 306 based on the confidence level and output a validation result 312 for simulated dataset 306. Validation result 312 indicates whether simulated dataset 306 is a realistic representation of real-world dataset 308, and may also indicate the accuracy and/or the confidence level of the classification. Validation result 312 may be represented by one or more data types, including, but not limited to, integers, floating-point numbers, character strings, booleans, and others.

In some embodiments, the confidence level may be represented as an area under the curve (AUC) score, which indicates the ability to distinguish between the simulated and real-world data in classification machine learning model 310. The AUC score is a summary metric of the receiver operating characteristic (ROC) curve, reflecting the classification machine learning model 310's ability to distinguish between simulated and real-world instance 318. An ROC curve is a graphical plot that illustrates the performance of a classifier, such as classification machine learning model 310, at varying threshold values. AUC values range from 0.5 to 1.0, with an AUC value of 0.5 indicating that the model's ability to distinguish between simulated and real-world instance 318 is no better than chance. An AUC of 1 indicates that the classification machine learning model 310 can perfectly distinguish between all simulated and real-world instance 318.

FIG. 3B is a schematic diagram of an example environment in which an autonomous vehicle 100 could operate. In the example embodiment, an instance in real-world dataset 308 and simulated dataset 306 describes a behavior with parameters. As used herein, a behavior refers to a scenario in the environment that a vehicle could encounter. Real-world dataset 308 and simulated dataset 306 correspond to the same behavior. Examples of behaviors include, but are not limited to, merge, aborted cut-in, lost cargo, crash, military convoy, wrong-way driver, runaway tires, road obstructions, police chase, bridge collapse, leading vehicle, trailing vehicle, stoplight, and others. FIG. 3B illustrates a cut-in behavior 314, where a car or target 316 moves from an adjacent lane to the same lane as autonomous vehicle 100. Some non-limiting examples of parameters specific to this behavior include, but are not limited to, the speed of autonomous vehicle 100, cut-in start position, cut-in duration, and cut-in side (e.g., the left or right side of ego or autonomous vehicle 100. Parameters may be represented by any data types, including but not limited to, integers, floating points, character strings, booleans, and others. Parameters may be referred to as features.

FIG. 3C is an example instance 318 of behavior 314. In the example embodiment, instance 318 or a sample of behavior 314 is represented as a feature vector 320. A feature vector is an array of elements, where each element corresponds to a value or a range of value of the feature at the corresponding index. For example, for an instance of cut-in behavior 314, parameters may be duration 324 of the behavior, longitudinal distance 322-s from ego/autonomous vehicle 100 to target 316 at the start of behavior 314, longitudinal distance 322-e from ego/autonomous vehicle 100 to target 316 at the end of behavior 314, velocity 326 of target 316, acceleration 328 of target 316, and so on. A feature vector of an instance of behavior 314 may be represented as [5, 25, 5, 33, 3, . . . ], which indicates for this instance 318, duration 324 of behavior 314 is 5 seconds, longitudinal distance 322-s at the start is 25 m, longitudinal distance 322-e at the end is 5 m, velocity 326 of target 316 is 33 m/s, and acceleration 328 of 316 is 3 m/s². In operation, simulated dataset 306 and real-world dataset 308 may be represented in feature vectors 320. Features vectors 320 are in input into classification machine learning model 310 to be classified.

In some embodiments, simulated dataset 306 and real-world dataset 308 are represented in the form of sensor data. For example, LiDAR, radar, images, video, audio, RFID, and others. The sensor data may be aggregated and/or processed into behaviors and/or parameters.

In some embodiments, simulated dataset 306 and real-world dataset 308 are unbalanced from one another. For example, simulated dataset 306 may include more instances of behavior 314 than real-world dataset 308, or real-world dataset 308 may include more instances than simulated dataset 306. In other embodiments, the number of instances in simulated dataset 306 and real-world dataset 308 are balanced, such that simulated dataset 306 includes the same number of instances as or a similar number of instances to real-world dataset 308, where the difference of instances between simulated dataset 306 and real-world dataset 308 is equal to or less than a threshold.

FIG. 3D is a schematic diagram of an example binary classification plot 330. Binary classification plot 330 illustrates the classification of two datasets described by two parameters 336, where each parameter is represented as a dimension on the plot. In this example, a decision boundary 332 separates the two classes. Points on one side of the boundary are classified as one class, and points on the other side are classified as the other class. Two parameters 336 are used as an example for illustration purposes only. Real-world dataset 308 and simulated dataset 306 include a relatively large number of parameters, for example 100 parameters or more, rendering the classification is a high-dimension problem.

FIG. 3E is a schematic diagram of an example dataset feature plot 334, which may be used to manually compare real-world dataset 308 with simulated dataset 306. A feature plot illustrates comparison of representation of a single parameter of target velocity 326 at the start, in real-world dataset 308 and simulated dataset 306. To generate feature plot 334, values of parameter 336 in simulated dataset 306 and real-world dataset 308 are plotted along the x-axis. As shown in plot 334, in a first range 338-1 of target velocity 326, simulated dataset 306 matches real-world dataset 308, but simulated dataset 306 misrepresentation of a second range 338-2 of target velocity 326 in real-world dataset 308. Manual comparison of real-world dataset 308 is time consuming and labor intensive because the comparison is one parameter at a time. In contrast, the systems and methods described herein are advantageous in providing a solution to a high-dimension problem with increased speed and reduced costs and time. Parameters are compared between simulated dataset 306 and real-world dataset 308 all at once.

In some embodiments, simulated dataset 306 oversamples critical areas for testing the performance of autonomy computing system 200. The validation result of simulated dataset 306 using classification machine learning model 310 may be used to verify that simulated dataset 306 samples critical areas in the spectra of parameters. For example, simulated dataset 306 sampling an area in the spectra of parameters likely being critical is generated. Simulated dataset 306 and real-world dataset 308 are input into classification machine learning model 310. Validation results 312 indicating that simulated dataset 306 is not realistic verifies the critical areas are sampled. The process may be repeated to oversample the critical areas. The generated simulated datasets are advantageous in testing performance of autonomy computing system 200, with much reduced difficulties, expenses, and risks, compared to acquiring real-world datasets in the critical areas.

FIG. 4 is a block diagram of an example simulation validation flowchart 400. In the example embodiment, simulated dataset 306 is generated by a data generator 402. Data generator 402 may run various behavior simulations. Simulated dataset 306 is output from data generator 402 in the same data format as real-world dataset 308 and describes the same combination of behaviors. In some embodiments, data generator 402 may be tuned based on one or more outputs from classification machine learning model 310 to generate an improved simulated dataset 306.

Instances of behavior 314 from the two sources are represented in parameters. For example, parameters such as velocity, heading, and distance at the start may be used. Instances of behavior 314 may be represented as feature vectors 320. Simulated dataset 306 and real-world dataset 308 are then provided as input to classification machine learning model 310. Classification machine learning model 310 classifies the inputs into two classes. If the confidence level of the classification into two classes is relatively high, real-world dataset 308 and simulated dataset 306 do not match, indicating simulated dataset 306 is not realistic. If the confidence level is relatively low, real-world dataset 308 and simulated dataset 306 match, indicating simulated dataset 306 is realistic. Classification machine learning model 310 may use any suitable algorithms, including but not limited to, decision trees, support vector machines, complex deep learning methods, or others.

In some embodiments, classification machine learning model 310 may provide explanation why simulated dataset 306 is distinct from real-world dataset 308. For example, classification machine learning model 310 provides one or more parameters that cause the divergence of simulated dataset 306 from real-world dataset 308. Classification machine learning model 310 such as a decision tree machine learning model may be used to explain the distinction. The explanation of the distinction may be generated by going through the decision tree and determining the feature(s) distinguishing real-world dataset 308 from simulated dataset 306.

The distinguishing features may serve as feedback to data generator 402. Referring back to FIG. 3E, classification machine learning model 310 outputs a distinguishing feature of target velocity 326 at the start at 35 m/s or higher. The level of being realistic in simulated dataset 306 may be increased by increasing instances of behavior 314 having the distinguishing feature. The process of improvement may be repeated until one or more desired criteria are met.

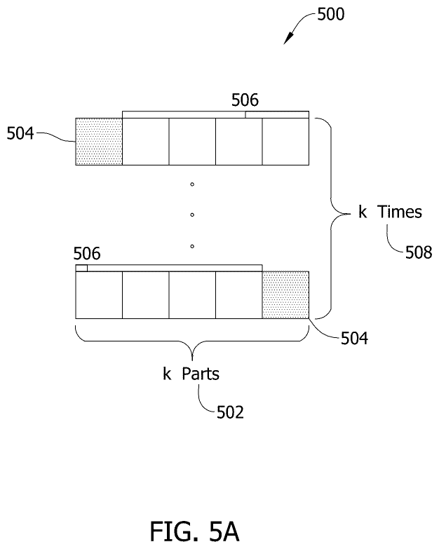

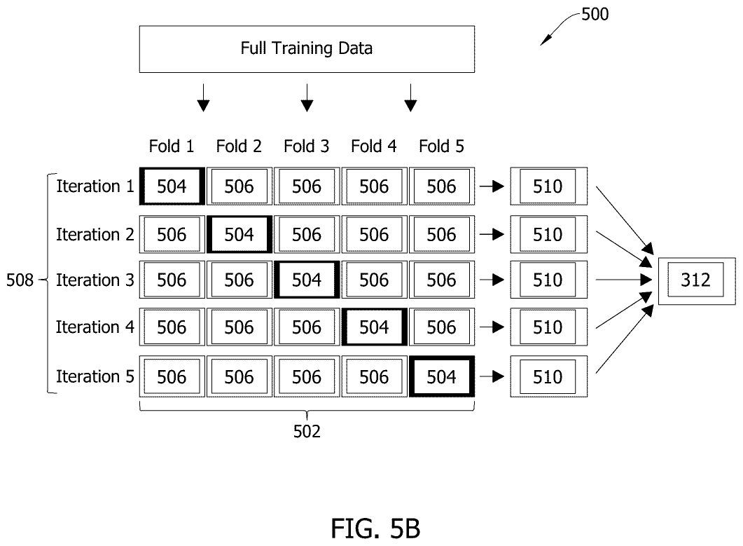

FIGS. 5A and 5B are schematic diagram of example classification machine learning model validation methods 500. In developing a machine learning model, the machine learning model is trained with training datasets, and the trained machine learning model is tested with a testing dataset to evaluate the performance of the trained machine learning model. In the example embodiment, cross-validation is used to validate classification machine learning model 310. Specifically, a k-fold cross-validation method 500 divides data into k parts 502. Simulated dataset 306 may be shuffled randomly before the division. The k−1 parts of the total k parts 502 are assigned as a training dataset 506. The remaining one part of the total k parts 502 is assigned to a testing dataset 504. Classification machine learning model 310 is trained using training dataset 504. Trained classification machine learning model 310 is tested using testing dataset 504. Assigning k−1 parts to training datasets 506, assigning the remaining one part to test dataset 504, training using training dataset 506, and testing with testing dataset 504 are repeated k−1 iterations 508.

FIG. 5B illustrates an example embodiment where performance indicator 510 is output for each iteration 508. These performance indicators 510 may be used to calculate validation results 312.

In some embodiments, k−x parts of the total k parts 502 is assigned to a training dataset 506 and x parts of the total k parts 502 are assigned to a test dataset 504, where x is an integer greater than 1 but less than k. In some further embodiments, any part of the total k parts 502 may only be assigned as to test dataset 504 one time.

Validation results 312 may be metrics describing the performance of classification machine learning model 310. Example metrics include but not limited to precision, recall, F1 score, and others. The metrics may be based on balanced or unbalanced datasets. For example, the simulated instances may outnumber the real-world instances, or vice versa.

Using k-fold cross-validation to validate classification machine learning model 310 is advantageous in increasing reliability of the validation results 312, where validation results 312 do not rely on the presentation of the development data. Using k-fold cross-validation to validate classification machine learning model 310 is also advantageous in reducing computation during development by enabling use of a development dataset of a reduced size for validating a machine learning model while maintaining the level of validation reliability.

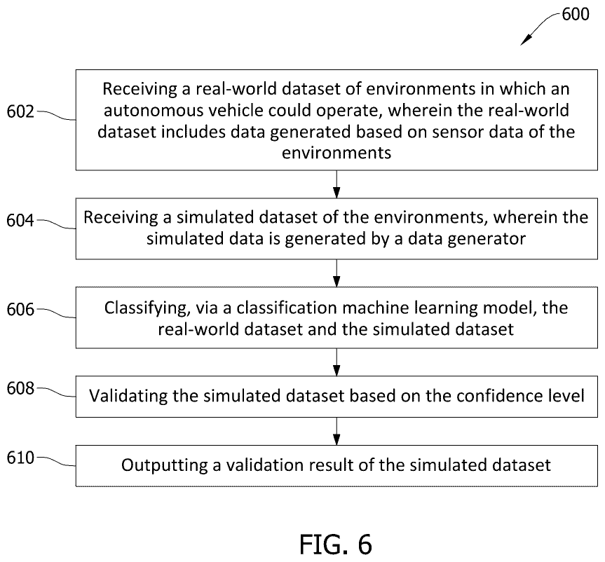

FIG. 6 is a flowchart of an of an example simulation validation method 600. Method 600 includes receiving 602 a real-world dataset of environments in which an autonomous vehicle could operate. The real-world dataset includes data generated based on sensor data of the environments. Method 600 also includes receiving 604 a simulated dataset of the environments. The simulated dataset is generated by a data generator. The method further includes classifying 606, via a classification machine learning model, the real-world dataset, and the simulated dataset. The datasets are input into the classification machine learning model, where the classification machine learning model is configured to classify input data into two classes. Method 600 additionally includes validating 608 the simulated dataset as being realistic based on classification. Method 600 also includes outputting 610 a validation result of the simulated dataset.

Additionally, Method 600 includes classifying 606 real-world dataset and simulated dataset. Classification is performed using a classification machine learning model. Real-world and simulated datasets are input into the model, which is configured to classify the input data into two categories and output a confidence level, reflecting the level of confidence in classifying the inputs into two classes. Furthermore, method 600 includes validating the simulated dataset based on this confidence level. If the confidence level is relatively high, simulated dataset 306 is validated as being realistic in representing real-world dataset 308. If the confidence level is relatively low, simulated dataset 306 is not validated, or the simulated dataset is not realistic in representing real-world dataset 308. A threshold may be used in validating simulated dataset 306. The threshold may be pre-defined, or user defined. Method 600 concludes with outputting a validation result.

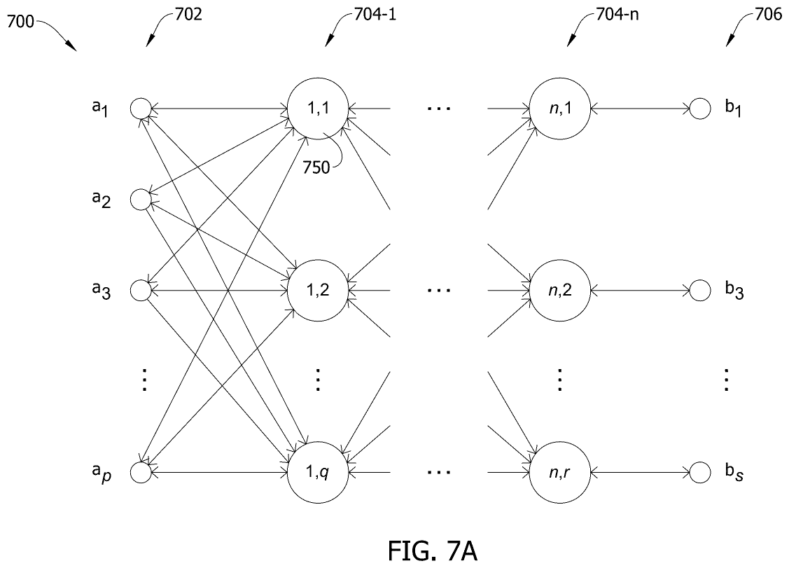

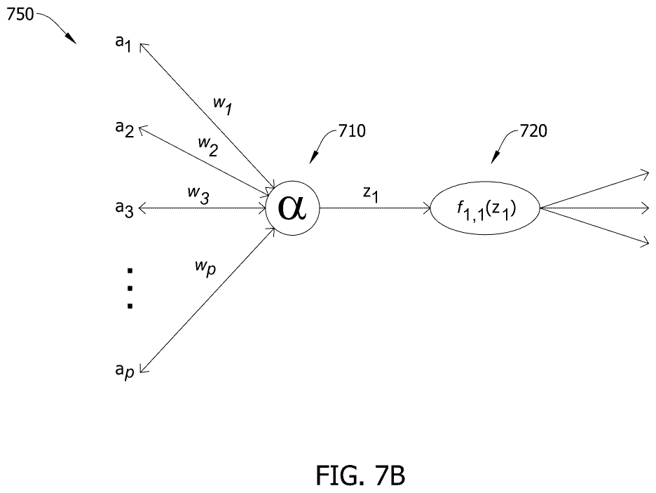

FIG. 7A depicts an example artificial neural network model 700. Classification machine learning model 310 may be implemented with one or more neural network model 700. In the example embodiment, neural network model 700 includes layers of neurons 702, 704-1 to 704-n, and 706, including an input layer 702, one or more hidden layers 704-1 through 704-n, and an output layer 706. Each layer may include any number of neurons, i.e., q, r, and n in FIG. 7A may be any positive integer. It should be understood that neural networks of a different structure and configuration from that depicted in FIG. 7A may be used to achieve the methods and systems described herein.

In the example embodiment, input layer 702 may receive different input data. For example, input layer 702 includes a first input a1 representing training images, a second input a2 representing patterns identified in the training images, a third input a3 representing edges of the training images, and so on. Input layer 702 may include thousands or more inputs. In some embodiments, the number of elements used by neural network model 700 changes during the training process, and some neurons are bypassed or ignored if, for example, during execution of the neural network, they are determined to be of less relevance.

In the example embodiment, each neuron in hidden layer(s) 704-1 through 704-n processes one or more inputs from input layer 702, and/or one or more outputs from neurons in one of the previous hidden layers, to generate a decision or output. Output layer 706 includes one or more outputs each indicating a label, confidence factor, weight describing the inputs, and/or an output image. In some embodiments, however, outputs of neural network model 700 are obtained from a hidden layer 704-1 through 704-n in addition to, or in place of, output(s) from output layer(s) 706.

In some embodiments, each layer has a discrete, recognizable function with respect to input data. For example, if n is equal to 3, a first layer analyzes the first dimension of the inputs, a second layer analyzes the second dimension, and the final layer analyzes the third dimension of the inputs. Dimensions may correspond to aspects considered strongly determinative, then those considered of intermediate importance, and finally those of less relevance.

In other embodiments, the layers are not clearly delineated in terms of the functionality they perform. For example, two or more of hidden layers 704-1 through 704-n may share decisions relating to labeling, with no single layer making an independent decision as to labeling.

FIG. 7B depicts an example neuron 750 that corresponds to the neuron labeled as “1,1” in hidden layer 704-1 of FIG. 7A, according to one embodiment. Each of the inputs to neuron 750 (e.g., the inputs in input layer 702 in FIG. 7A) is weighted such that input a1 through ap corresponds to weights w1 through wp as determined during the training process of neural network model 700.

In some embodiments, some inputs lack an explicit weight, or have a weight below a threshold. The weights are applied to a function α (labeled by a reference numeral 710), which may be a summation and may produce a value z1 which is input to a function 720, labeled as f1,1(z1). Function 720 is any suitable linear or non-linear function. As depicted in FIG. 7B, function 720 produces multiple outputs, which may be provided to neuron(s) of a subsequent layer or used as an output of neural network model 700. For example, the outputs may correspond to index values of a list of labels or may be calculated values used as inputs to subsequent functions.

It should be appreciated that the depicted structure and function of neural network model 700 and neuron 750 are for illustration purposes only, and that other suitable configurations exist. For example, the output of any given neuron may depend not only on values determined by past neurons, but also on future neurons.

Neural network model 700 may include a convolutional neural network (CNN), a deep learning neural network, a reinforced or reinforcement learning module or program, or a combined learning module or program that learns in two or more fields or areas of interest. Supervised and unsupervised machine learning techniques may be used. In supervised machine learning, a processing element may be provided with example inputs and their associated outputs and may seek to discover a general rule that maps inputs to outputs, so that when subsequent novel inputs are provided the processing element may, based upon the discovered rule, accurately predict the correct output. Neural network model 700 may be trained using unsupervised machine learning programs. In unsupervised machine learning, the processing element may be required to find its own structure in unlabeled example inputs. Machine learning may involve identifying and recognizing patterns in existing data in order to facilitate making predictions for subsequent data. Models may be created based upon example inputs in order to make valid and reliable predictions for novel inputs.

Additionally, or alternatively, the machine learning programs may be trained by inputting sample datasets or certain data into the programs, such as images, object statistics, and information. The machine learning programs may use deep learning algorithms that may be primarily focused on pattern recognition and may be trained after processing multiple examples. The machine learning programs may include Bayesian Program Learning (BPL), voice recognition and synthesis, image or object recognition, optical character recognition, and/or natural language processing—either individually or in combination. The machine learning programs may also include natural language processing, semantic analysis, automatic reasoning, and/or machine learning.

Based upon these analyses, neural network model 700 may learn how to identify characteristics and patterns that may then be applied to analyzing image data, model data, and/or other data. For example, neural network model 700 may learn to identify features in a series of instances.

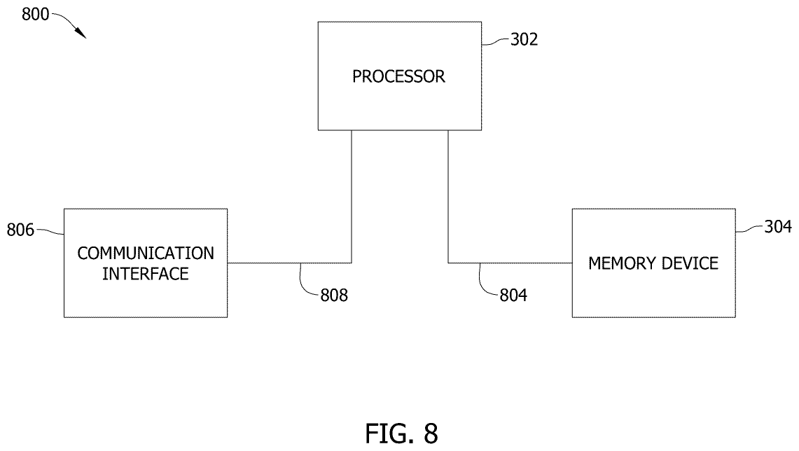

FIG. 8 is a block diagram of an example computing device 800. Autonomy computing device 200 may be implemented with one or more computing devices 800. Computing device 800 includes a processor 302 and a memory device 304. Processor 302 is coupled to memory device 304 via a system bus 804. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are example only, and thus are not intended to limit in any way the definition or meaning of the term “processor.”

In the example embodiment, memory device 304 includes one or more devices that enable information, such as executable instructions or other data (e.g., sensor data), to be stored and retrieved. Moreover, memory device 304 includes one or more computer readable media, such as, without limitation, dynamic random-access memory (DRAM), static random-access memory (SRAM), a solid-state disk, or a hard disk. In the example embodiment, memory device 304 stores, without limitation, application source code, application object code, configuration data, additional input events, application states, assertion statements, validation results, or any other type of data. Computing device 800, in the example embodiment, may also include a communication interface 806 that is coupled to processor 302 via system bus 808. Moreover, communication interface 806 is communicatively coupled to data acquisition devices.

In the example embodiment, processor 302 may be programmed by encoding an operation using one or more executable instructions and providing the executable instructions in memory device 304. In the example embodiment, processor 302 is programmed to select a plurality of measurements that are received from data acquisition devices.

In operation, a computer executes computer-executable instructions embodied in one or more computer-executable components stored on one or more computer-readable media to implement aspects of the disclosure described or illustrated herein. The order of execution or performance of the operations in embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

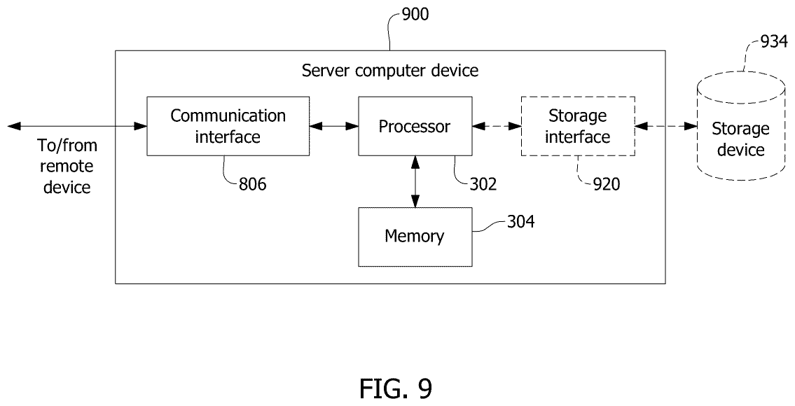

FIG. 9 is a block diagram of an example server computing device 900. Simulation validation computing device 300 may be implemented with one or more server computing device 900. Server computer device 900 also includes a processor 302 for executing instructions. Instructions may be stored in a memory area 304, for example. Processor 302 may include one or more processing units (e.g., in a multi-core configuration).

Processor 302 is operatively coupled to a communication interface 806 such that server computer device 900 is capable of communicating with a remote device or another server computer device 900. For example, communication interface 806 may receive data from autonomy computing system 200 or sensors 202, via the Internet or wireless communication.

Processor 302 may also be operatively coupled to a storage device 934. Storage device 934 is any computer-operated hardware suitable for storing and/or retrieving data. In some embodiments, storage device 934 is integrated in server computer device 900. For example, server computer device 900 may include one or more hard disk drives as storage device 934. In other embodiments, storage device 934 is external to server computer device 900 and may be accessed by a plurality of server computer devices 900. For example, storage device 934 may include multiple storage units such as hard disks and/or solid-state disks in a redundant array of independent disks (RAID) configuration. Storage device 934 may include a storage area network (SAN) and/or a network attached storage (NAS) system.

In some embodiments, processor 302 is operatively coupled to storage device 934 via a storage interface 920. Storage interface 920 is any component capable of providing processor 302 with access to storage device 934. Storage interface 920 may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing processor 302 with access to storage device 934.

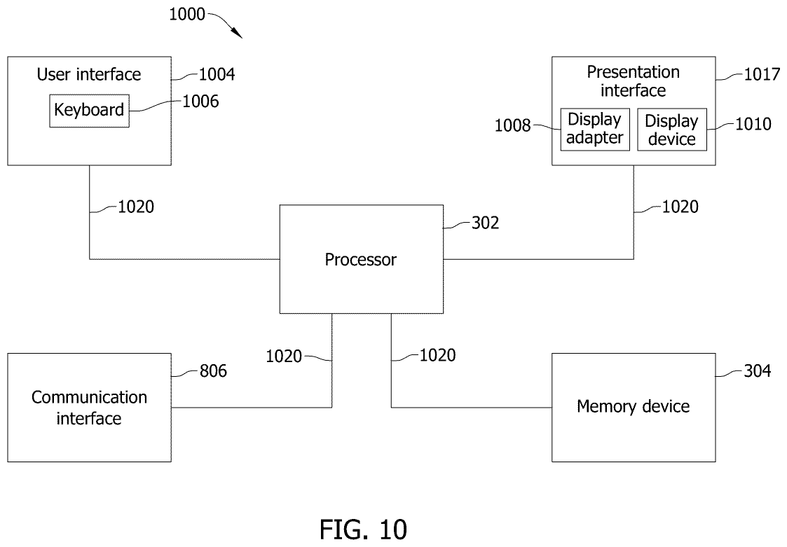

FIG. 10 is a block diagram of an example user computing device 1000. Simulation validation computing device 300 may be implemented with one or more user computing device 1000. In the exemplary embodiment, computing device 1000 includes a user interface 1004 that receives at least one input from a user. User interface 1004 can include a keyboard 1006 that enables the user to input pertinent information. User interface 1004 can also include, for example, a pointing device, a mouse, a stylus, a touch sensitive panel (e.g., a touch pad and a touch screen), a gyroscope, an accelerometer, a position detector, and/or an audio input interface (e.g., including a microphone).

Moreover, in the exemplary embodiment, computing device 1000 includes a presentation interface 1017 that presents information, such as input events and/or validation results, to the user. Presentation interface 1017 can also include a display adapter 1008 that is coupled to at least one display device 1010. More specifically, in the exemplary embodiment, display device 1010 can be a visual display device, such as a cathode ray tube (CRT), a liquid crystal display (LCD), a light-emitting diode (LED) display, and/or an “electronic ink” display. Alternatively, presentation interface 1017 can include an audio output device (e.g., an audio adapter and/or a speaker) and/or a printer.

Computing device 1000 also includes a processor 302 and a memory device 304. Processor 302 is coupled to user interface 1004, presentation interface 1017, and memory device 304 via a system bus 1020. In the exemplary embodiment, processor 302 communicates with the user, such as by prompting the user via presentation interface 1017 and/or by receiving user inputs via user interface 1004. The term “processor” refers generally to any programmable system including systems and microcontrollers, RISC, CISC, ASIC, PLC, and any other circuit or processor capable of executing the functions described herein. The above examples are exemplary only, and thus are not intended to limit in any way the definition and/or meaning of the term “processor.”

In the exemplary embodiment, memory device 304 includes one or more devices that enable information, such as executable instructions and/or other data, to be stored and retrieved. Moreover, memory device 304 includes one or more computer readable media, such as, without limitation, DRAM, SRAM, a solid-state disk, and/or a hard disk. In the exemplary embodiment, memory device 304 stores, without limitation, application source code, application object code, configuration data, additional input events, application states, assertion statements, validation results, and/or any other type of data. Computing device 1000, in the exemplary embodiment, can also include a communication interface 806 that is coupled to processor 302 via system bus 1020. Moreover, communication interface 806 is communicatively coupled to data acquisition devices.

In the exemplary embodiment, processor 302 can be programmed by encoding an operation using one or more executable instructions and providing the executable instructions in memory device 304. In the exemplary embodiment, processor 302 is programmed to select a plurality of measurements that are received from data acquisition devices.

In operation, a computer executes computer-executable instructions embodied in one or more computer-executable components stored on one or more computer-readable media to implement aspects of the invention described and/or illustrated herein. The order of execution or performance of the operations in embodiments of the invention illustrated and described herein is not essential, unless otherwise specified. That is, the operations can be performed in any order, unless otherwise specified, and embodiments of the invention can include additional or fewer operations than those disclosed herein. For example, it is contemplated that executing or performing a particular operation before, contemporaneously with, or after another operation is within the scope of aspects of the invention.

In some embodiments, simulation validation computing device 300 is implemented with a combination of computer device 800, server computing device 900 and user computer device 1000.

### MACHINE LEARNING & OTHER MATTERS

The computer-implemented methods discussed herein may include additional, less, or alternate actions, including those discussed elsewhere herein. The methods may be implemented via one or more local or remote processors, transceivers, and/or sensors (such as processors, transceivers, and/or sensors mounted on mobile devices, or associated with smart infrastructure or remote servers), and/or via computer-executable instructions stored on non-transitory computer-readable media or medium.

Additionally, the computer systems discussed herein may include additional, less, or alternate functionality, including that discussed elsewhere herein. The computer systems discussed herein may include or be implemented via computer-executable instructions stored on non-transitory computer-readable media or medium.

A processor or a processing element may be trained using supervised or unsupervised machine learning, and the machine learning program may employ a neural network, which may be a convolutional neural network, a deep learning neural network, a reinforced or reinforcement learning module or program, or a combined learning module or program that learns in two or more fields or areas of interest. Machine learning may involve identifying and recognizing patterns in existing data in order to facilitate making predictions for subsequent data. Models may be created based upon example inputs in order to make valid and reliable predictions for novel inputs.

Additionally, or alternatively, the machine learning programs may be trained by inputting sample (e.g., training) datasets or certain data into the programs, such as conversation data of spoken conversations to be analyzed, mobile device data, and/or additional speech data. The machine learning programs may utilize deep learning algorithms that may be primarily focused on pattern recognition and may be trained after processing multiple examples. The machine learning programs may include Bayesian program learning (BPL), voice recognition and synthesis, image or object recognition, optical character recognition, and/or natural language processing-either individually or in combination. The machine learning programs may also include natural language processing, semantic analysis, automatic reasoning, and/or other types of machine learning, such as deep learning, reinforced learning, or combined learning.

Supervised and unsupervised machine learning techniques may be used. In supervised machine learning, a processing element may be provided with example inputs and their associated outputs, and may seek to discover a general rule that maps inputs to outputs, so that when subsequent novel inputs are provided the processing element may, based upon the discovered rule, accurately predict the correct output. In unsupervised machine learning, the processing element may be required to find its own structure in unlabeled example inputs. The unsupervised machine learning techniques may include clustering techniques, cluster analysis, anomaly detection techniques, multivariate data analysis, probability techniques, unsupervised quantum learning techniques, associate mining or associate rule mining techniques, and/or the use of neural networks. In some embodiments, semi-supervised learning techniques may be employed. In one embodiment, machine learning techniques may be used to extract data about the conversation, statement, utterance, spoken word, typed word, geolocation data, and/or other data.

An example technical effect of the methods, systems, and apparatus described herein includes at least one of: (a) determining the validity of a given set of simulated data for use in developing autonomous vehicles using a classification machine learning model, where a simulated dataset and a real-world dataset as input into the classification machine learning model or (b) improving simulated data generation based on distinguishing features provided by the classification machine learning model.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A simulation validation computing device for validating simulated data for use in developing an autonomy computing system of an autonomous vehicle, comprising at least one processor in communication with at least one memory device, the at least one processor programmed to:
receive a real-world dataset of environments in which an autonomous vehicle could operate, wherein the real-world dataset includes data generated based on sensor data of the environments;
receive a simulated dataset of the environments, the simulated data of the simulated dataset generated by a data generator;
classify, via a classification machine learning model, the real-world dataset and the simulated dataset, by inputting the datasets into the classification machine learning model, wherein the classification machine learning model is configured to classify input data into two classes;
validate the simulated dataset as being realistic based on classification; and
output a validation result of the simulated dataset.

2. The simulation validation computing device of claim 1, wherein the classification machine learning model is configured to output a confidence level in classifying the real-world dataset and the simulated dataset into the two classes, the at least one processor is further programmed to:
validate the simulated dataset based on the confidence level.

3. The simulation validation computing device of claim 1, wherein the real-world dataset and the simulated dataset include data representing a behavior in the environments, the at least one processor is further programmed to:
represent the behavior with parameters, wherein the real-world dataset and the simulated dataset correspond to the same behavior.

4. The simulation validation computing device of claim 3, wherein the at least one processor is further programmed to:
represent the real-world dataset and the simulated dataset in feature vectors denoting instances of the behavior; and
classify the real-world dataset and the simulated dataset by inputting the feature vectors into the classification machine learning model.

5. The simulation validation computing device of claim 1, wherein the at least one processor is further programmed to:
provide, via the classification machine learning model, one or more distinguishing features between the real-world dataset and the simulated dataset; and
improve a level of being realistic in the simulated dataset based on the one or more distinguishing features.

6. The simulation validation computing device of claim 1, wherein the at least one processor is further programmed to:
validate the simulated dataset based on an area under curve score.

7. The simulation validation computing device of claim 1, wherein the classification machine learning model is validated by:
dividing the real-world dataset and the simulated dataset into k parts, wherein k denotes a number of parts into which the real-world dataset and the simulated dataset is divided;
assigning k−1 parts to a training dataset;
assigning the remaining one part to a test dataset;
training the classification machine learning model using the training dataset;
testing the classification machine learning model using the testing dataset; and
repeating assigning the k−1 parts, assigning the remaining one part, training, and testing k−1 times.

8. The simulation validation computing device of claim 1, wherein the at least one processor is further programmed to:
generate the simulated dataset including parameters likely in critical areas; and
classify the real-world dataset and the simulated dataset to verify the simulated dataset including the parameters in the critical areas.

9. A computer-implemented method for validating simulated data for use in developing an autonomy computing system of an autonomous vehicle, comprising:
receiving a real-world dataset of environments in which an autonomous vehicle could operate, wherein the real-world dataset includes data generated based on sensor data of the environments;
receiving a simulated dataset of the environments, the simulated data generated by a data generator;
classifying, via a classification machine learning model, the real-world dataset and the simulated dataset, by inputting the datasets into the classification machine learning model, wherein the classification machine learning model is configured to classify input data into two classes;
validating the simulated dataset as being realistic based on classification; and
outputting a validation result of the simulated dataset.

10. The simulation validation method of claim 9, wherein the classification machine learning model is configured to output a confidence level in classifying the real-world dataset and the simulated dataset into the two classes, the method further comprising:
validating the simulated dataset based on the confidence level.

11. The simulation validation method of claim 9, wherein the real-world dataset and the simulated dataset include data representing a behavior in the environments, the method further comprising:
representing the behavior with parameters, wherein the real-world dataset and the simulated dataset correspond to the same behavior.

12. The simulation validation method of claim 9, further comprising:
providing, via the classification machine learning model, one or more distinguishing features between the real-world dataset and the simulated dataset; and
improving a level of being realistic in the simulated dataset based on the one or more distinguishing features.

13. One or more non-transitory computer-readable media for validating simulated data for use in developing an autonomy computing system of an autonomous vehicle, the one or more non-transitory computer-readable media comprising a plurality of instructions stored thereon that, in response to being executed, cause a system to:
receive a real-world dataset of environments in which an autonomous vehicle could operate, wherein the real-world dataset includes data generated based on sensor data of the environments;
receive a simulated dataset of the environments, the simulated data generated by a data generator;
classify, via a classification machine learning model, the real-world dataset and the simulated dataset, by inputting the datasets into the classification machine learning model, wherein the classification machine learning model is configured to classify input data into two classes;
validate the simulated dataset as being realistic based on classification; and
outputting a validation result of the simulated dataset.

14. The one or more non-transitory computer-readable media of claim 13, wherein the classification machine learning model is configured to output a confidence level in classifying the real-world dataset and the simulated dataset into the two classes the plurality of instructions further cause the system to:
validate the simulated dataset based on the confidence level.

15. The one or more non-transitory computer-readable media of claim 13, wherein the real-world dataset and the simulated dataset include data representing a behavior in the environments, the plurality of instructions further cause the system to:
represent the behavior with parameters, wherein the real-world dataset and the simulated dataset correspond to the same behavior.

16. The one or more non-transitory computer-readable media of claim 15, wherein the plurality of instructions further cause the system to:
represent the real-world dataset and the simulated dataset in feature vectors denoting instances of the behavior; and
classify the real-world dataset and the simulated dataset by inputting the feature vectors into the classification machine learning model.

17. The one or more non-transitory computer-readable media of claim 13, wherein the plurality of instructions further cause the system to:
provide, via the classification machine learning model, one or more distinguishing features between the real-world dataset and the simulated dataset; and
improve a level of being realistic in the simulated dataset based on the one or more distinguishing features.

18. The one or more non-transitory computer-readable media of claim 13, wherein the plurality of instructions further cause the system to:
validate the simulated dataset based on an area under curve score.

19. The one or more non-transitory computer-readable media of claim 13, wherein the plurality of instructions further cause the classification machine learning model to be validated by:
dividing the simulated dataset into k parts, wherein k denotes a number of parts into which the simulated dataset is divided;
assigning k−1 parts to a training dataset;
assigning the remaining one part to a test dataset;
training the classification machine learning model using the training dataset;
testing the classification machine learning model using the testing dataset; and
repeating assigning the k-1 parts, assigning the remaining one part, training, and testing k−1 times.

20. The one or more non-transitory computer-readable media of claim 13, wherein the plurality of instructions further cause the system to:
generate the simulated dataset including parameters likely in critical areas; and
classify the real-world dataset and the simulated dataset to verify the simulated dataset including the parameters in the critical areas.
